(19) United States
(12) Patent Application Publication
(10) Pub. No.: US 2006/0110934 A1
(43) Pub. Date: May 25, 2006

(54) Method and apparatus for forming insulating film

(76) Inventor: Yusuke Fukuchi, Ibaraki-ken (JP)

Correspondence Address: COWAN LIEBOWITZ & LATMAN P.C.;JOHN J TORRENTE, 1133 AVE OF THE AMERICAS, NEW YORK, NY, 10036, US

(21) Appl. No.: 11/268,819

(22) Filed: Nov. 8, 2005

(30) Foreign Application Priority Data
Nov. 8, 2004 (JP) 323693/2004(PAT.)

(51) Int. Cl. H01L 21/31; H01L 21/469

(52) U.S. Cl. 438/778

(57) ABSTRACT

The present invention provides a method and apparatus for forming an insulating film having good reliability, in accordance with a process without high-temperature heating. In accordance with the present invention, in a process for forming an insulating film for a semiconductor device by oxidizing a material to be processed, exposed at the surface of a substrate to be processed, in accordance with plasma oxidation method, the plasma processing is carried out by use of at least a gas that contains hydrogen atoms other than H₂ and H₂O and a gas that contains oxygen atoms other than H₂O.

### FIELD OF THE INVENTION AND RELATED ART

This invention relates generally to a semiconductor device manufacturing process. More particularly, the invention concerns an insulating film forming method and apparatus for forming an oxide film upon the surface of a wafer through plasma processing.

Conventionally, silicon dioxide films used as a gate insulating film of an MOS (Metal Oxide Semiconductor) type semiconductor device are produced in accordance with a oxidation method in which a silicon substrate is oxidized by heating it to a temperature of about 1000° C. in an oxidization ambience of dry oxygen or water vapor. With this method, however, an impurity layer already formed within the substrate may be re-diffused due to the heat, and the fineness may be prevented thereby. In consideration of this, a plasma oxidation method is becoming attractive because it can oxidize silicon at a lower temperature. In this plasma oxidation method, an oxidizing reaction gas is excited by means of a high frequency electric field and it is plasmatized, whereby a large amount of active radicals are produced. These radicals react with silicon easily even at a low temperature, such that the silicon can be oxidized quickly. Hence, the plasma oxidation method is regarded as one oxide film forming technique for next-generation semiconductor devices.

As regards reaction gases for such plasma oxidation, generally, an O₂ gas like the conventional thermal oxidation process, or a mixed gas that comprises O₂ gas diluted by an inactive gas or a rare gas such as He, Ne, Ar, Kr, Xe and N₂, for example, are usable. Alternatively, a mixed gas of O₂ and H₂ or H₂O may be used, and in that occasion, hydroxy radical (hereinafter “OH radical”) can be produced. The OH radical has high oxidation reduction potential as compared with active species such as superoxide anion radicals (.O₂⁻) or neutral oxygen radicals such as oxygen atoms, for example, as produced from O₂ plasma, and it has good oxidizing rate. Therefore, even at a low temperature it can achieve high speed silicon oxidization. Furthermore, hydrogen atoms contained in the gas described hereinbefore serve to terminate dangling bond of silicon produced in the oxide film when exposed to high speed ion bombardment in the plasma. Because of this, the plasma oxidation method is effective to produce high-quality oxide films that the defective density is low as compared with an oxide film produced by using an O₂ gas, and the leak electric current can be held low, while a change with respect to time due to weak leak current stress is small. Such oxide film may be suitably used as a tunnel oxide film of a flash memory, for example.

FIG. 4 is a graph showing an example of oxide film thickness versus H₂ content in a case where plasma oxidization of a silicon substrate is carried out by using a mixed gas of O₂ and H₂. It is seen from the graph that, the higher the H₂ content is, the larger the obtained oxide film thickness is. This may be a result of the increase in the produced amount of OH radicals. However, H₂ is a combustible gas and a mixed gas of H₂ and O₂ is explosive. In consideration of it, for safe handling, generally, what is called a foaming gas in which the gas is diluted by using an inactive gas such as Ar or N₂, to a low content of 4% or lower which is the lower explosive-free limit, is used. In such case, however, it is not easy to supply a sufficient content of H₂ into a reaction chamber and to produce a plenty of OH radicals.

On the other hand, where H₂O is vaporized by heat or N₂ bubbled and it is used as a reaction gas, since H₂O can be dissociated by plasma and it produces OH radicals, a plenty of OH radicals can be supplied without a risk of explosion as described above. However, regarding the gas gasified in accordance with the method described above, as compared with ordinary dry gases it is difficult to supply the same while controlling the flow rate stably. Furthermore, it is difficult to supply H₂O of certain purity constantly. Additionally, even if it is possible to supply high purity H₂O, a very small amount of a metal that constitutes the piping may be melted into H₂O to cause metal contamination. For these reasons, it is not suitable as a process gas for forming a gate insulating film for a semiconductor device which is very sensitive to contaminants in the film.

### SUMMARY OF THE INVENTION

It is accordingly an object of the present invention to provide a method and/or an apparatus for forming a silicon oxide film by oxidizing silicon through plasma, by which a large amount of OH radicals can be produced cleanly and safely and by which an insulating film having high reliability can be produced quickly.

In accordance with an aspect of the present invention, there is provided an insulating film forming method in which a material to be processed, which is exposed at a surface of a substrate to be processed, is oxidized in accordance with a plasma oxidation method and by use of at least a gas that contains hydrogen atoms other than H₂ and H₂O and a gas that contains oxygen atoms other than H₂O, to produce an insulating film for a semiconductor device.

In one preferred form of this aspect of the present invention, the gas that contains hydrogen atoms other than H₂ and H₂O may comprise one of NH₃, CH₄, HCl, HBr and HI, and the gas that contains oxygen atoms other than H₂O may comprise at least one of O₂, O₃, NO, N₂O, NO₂, CO and CO₂.

The plasma oxidation process may be carried out while the substrate to be processed is placed on a support table, and the support table may be maintained at a temperature not greater than 600° C.

The material exposed at the surface of the substrate to be processed may comprise at least one of monocrystal silicon, polycrystal silicon, amorphous silicon, silicon carbide and silicon germanium.

The plasma oxidation process may use a plasma source which is based on surface wave plasma.

In accordance with another aspect of the present invention, there is provided an insulating film forming apparatus in which a material to be processed, which is exposed at a surface of a substrate to be processed, is oxidized by use of plasma oxidizing means to produce an insulating film for a semiconductor device, characterized by means for performing plasma processing by use of at least a gas that contains hydrogen atoms other than H₂ and H₂O and a gas that contains oxygen atoms other than H₂O.

In such insulating film forming apparatus as well, the gas that contains hydrogen atoms other than H₂ and H₂O may comprise one of NH₃, CH₄, HCl, HBr and HI, and the gas that contains oxygen atoms other than H₂O may comprise at least one of O₂, O₃, NO, N₂O, NO₂, CO and CO₂. The plasma oxidation process may be carried out while the substrate to be processed is placed on a support table, and the support table may be maintained at a temperature not greater than 600° C. The material exposed at the surface of the substrate to be processed may comprise at least one of monocrystal silicon, polycrystal silicon, amorphous silicon, silicon carbide and silicon germanium. The plasma oxidation process may use a plasma source which is based on surface wave plasma.

In accordance with the present invention, it is enabled to provide a method and/or an apparatus for forming a silicon oxide film by oxidizing silicon through plasma, by which a large amount of OH radicals can be produced cleanly and safely and by which an insulating film having high reliability can be produced quickly. More specifically, the method and apparatus of the present invention can produce a high-quality insulating film having good insulating property and low leak current characteristic. Silicon oxide films produced in accordance with the present invention can be used as an MOS transistor gate insulating film, or a gate insulating film for a flash memory, for example.

These and other objects, features and advantages of the present invention will become more apparent upon a consideration of the following description of the preferred embodiments of the present invention taken in conjunction with the accompanying drawings.

### BRIEF DESCRIPTION OF THE DRAWINGS

FIG. 1 is a schematic and sectional view of a microwave plasma processing apparatus according to an embodiment of the present invention.

FIG. 2 is a schematic and sectional view of a plasma processing apparatus according to an embodiment of the present invention.

FIG. 3 is a graph for explaining current-to-voltage characteristics of an oxide film produced in accordance with an embodiment of the present invention and of a conventional thermal oxidation film.

FIG. 4 is a graph showing an example of a relation between hydrogen content and oxide film thickness, in plasma oxidation.

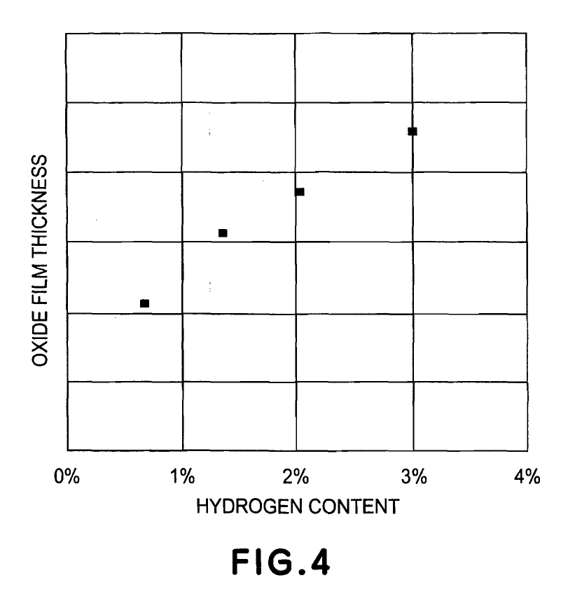

### DESCRIPTION OF THE PREFERRED EMBODIMENTS

Preferred embodiments of the present invention will now be described with reference to the attached drawings.

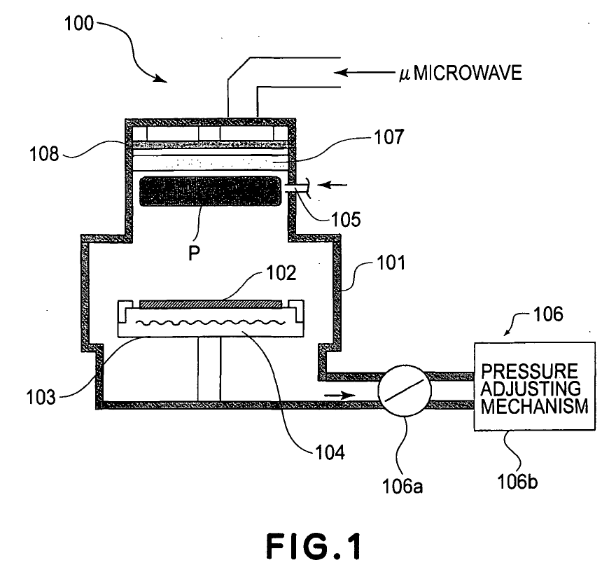

A plasma processing apparatus (hereinafter, “processing apparatus”) according to an embodiment of the present invention will now be explained in conjunction with FIG. 1. FIG. 1 is a schematic and sectional view of the processing apparatus 100. The processing apparatus 100 is connected to a microwave producing source or a high frequency source (both not shown), and it comprises a vacuum container (plasma processing chamber) 101, a substrate 102 to be processed, a support table 103, a temperature control unit 104, a gas introducing portion 105, a pressure adjusting mechanism 106, a dielectric material window or a high-frequency wave transmitting means 107, and a microwave supplying means or high-frequency voltage supplying means 108. The processing apparatus is arranged to perform plasma processing to the substrate 102 to be processed.

The microwave producing source may comprise a magnetron, for example, and it produces microwaves of 2.45 GHz, for example. It should be noted however that, in the present invention, the microwave frequency can be chosen as desired out of a range from 0.8 GHz to 20 GHz. The microwave is then converted into TM or TE mode, for example, by means of a mode converter (not shown), and it is propagated through a waveguide tube. Along the propagation path of the microwave, there are isolators and impedance matching device, for example. The isolator is provided to prevent reflected microwaves from turning back to the microwave producing source, and it functions to absorb such reflected waves. The impedance matching device includes a power meter for detecting the intensity and phase of each of an advancing wave supplied from the microwave producing source toward the load, and a reflected wave being reflected by the load and going back to the microwave producing source. The impedance matching device has a function for providing matching between the microwave producing source and the load side, and it may comprise a 4E tuner, an EH tuner or a stub tuner, for example.

The plasma processing chamber 101 is a vacuum container that accommodates therein a substrate 102 to be processed and that is arranged to perform plasma processing to the substrate 102 in a vacuum or reduced pressure ambience. In FIG. 1, a mechanism for transferring the substrate 102 between the chamber 102 and a load-lock chamber (not shown), that is, a gate valve, for example, is unshown.

The substrate 102 to be processed is a silicon substrate, in this embodiment. It should be noted however that the substrate 102 usable with this embodiment may be semiconductive or electrically conductive or, alternatively, it may be even an electrically insulating member, as long as it has a material to be processed which material is provided on the surface of the substrate 102 and which material is chosen at least from monocrystal silicon, polycrystal silicon, amorphous silicon, silicon carbide and silicon germanium. In the case of electrically conductive substrate, it may be made of metal such as Fe, Ni, Cr, Al, Mo, Au, Nb, Ta, V, Ti, Pt or Pb, for example, or an alloy of these materials such as brass or stainless steel, for example. As regards an electrically insulating substrate, examples are SiO₂ series quartz or various glasses, an inorganic substance such as Si₃, N₄, NaCl, KCl, LiF, CaF₂, BaF₂, Al₂O₃, AlN or MgO, and a film of organic substance such as polyethylene, polyester, polycarbonate, cellulose acetate, polypropylene, polyvinyl chloride, polyvinylidene chloride, polystyrene, polyamide or polyimide.

The substrate 102 is mounted on the support table 103. If necessary, the support table 103 may be arranged so that its level (height) is adjustable. The support table 103 is accommodated in the plasma processing chamber 101, and it supports the substrate 102 to be processed.

The temperature adjusting unit 104 comprises a heater, for example, and it is controlled at a temperature suitable for the processing, such as not greater than 600° C., for example, more preferably, in a range from 200° C. to 400° C., for example. The temperature adjusting unit 104 includes a temperature gauge, for example, for measuring the temperature of the support table 103, and a controller for controlling energization of a heater wire (temperature adjuster) from a voltage source (not shown) so that the temperature measured by the temperature gauge is brought to a predetermined temperature. The temperature not greater than 600° C. is set for the reason that a high temperature would accelerate diffusion of impurities already produced in the substrate and the fineness would be prevented.

The gas introducing portion (inlet) 105 is provided above the plasma processing chamber 101, and it serves to supply a plasma processing gas into the plasma processing chamber 101. The gas introducing portion 105 is one of the components of gas supplying means which include a gas supply source, a valve, a mass-flow controller, and a gas introducing tube that connects these components. The gas supplying means supplies a processing gas or electrically discharging gas to produce predetermined plasma when excited by microwaves. The gas introducing portion 105 may be separated into an introducing portion for introducing a processing gas and another introducing portion for introducing an inactive gas, and these introducing portions may be provided at different positions.

The oxidizing gas for oxidation and surface treatment of the substrate 102 consists of a gas having oxygen atoms chosen at least from O₂, O₃, NO, N₂O and NO₂, and a gas having hydrogen atoms chosen at least from NH₃, CH₄, HCl, HBr and HI. The processing gas may be provided by a mixed gas as diluted by one or more gases of He, Ne, Ar, Kr, Xe and N₂. Particularly, since a rare gas such as He or Ar, for example, is ionized easily, an advantageous effect of igniting the plasma quickly and stably is available. Furthermore, because is has no reactivity, there is no risk of adverse influence upon the substrate 102 to be processed.

The pressure adjusting mechanism 106 is disposed in the lower portion of or at the bottom of the plasma processing chamber 101, and it provides a pressure adjusting mechanism in conjunction with a pressure adjusting valve 106a, a pressure gauge (not shown), a vacuum pump 106b and a controller (not shown). The unshown controller serves to adjust the pressure inside the plasma processing chamber 101 so that the pressure level inside the chamber as measured by the pressure gauge is brought to a predetermined value. To this end, the controller controls the pressure adjusting valve 106a (which may be a gate valve with pressure adjusting function available from VAT Co. or an exhaust slot valve available from MKS Co.) arranged to adjust the pressure inside the plasma processing chamber on the basis of the degree of opening of the valve. With this arrangement, the pressure processing apparatus 100 controls the inside pressure of the plasma processing chamber 101 through the pressure adjusting mechanism 106, to a level suitable for the processing.

The vacuum pump 106a comprises a turbo molecular pump (TMP), for example, and it is connected to the plasma processing chamber 101 through a pressure adjusting valve such as a conductance valve (not shown), for example.

The dielectric material window 107 serves to transmit microwaves supplied from the microwave producing source, toward the plasma processing chamber 101 and, additionally, it functions as a partition wall for the plasma processing chamber 101.

The planar microwave supplying means with slots (108) is provided to introduce microwaves into the plasma processing chamber 101 through the dielectric material window 107. The microwave supplying means may be anyone such as a slotted endless circular waveguide or a coaxial introducing planar multi-slot antenna, for example, as long as it can provide planar microwaves. As regards the material for the microwave supplying means 108 usable in the present invention, although any electrically conductive material may be used, for least propagation loss of microwaves, use of Al, Cu, Ag/Cu plated SUS having high conductivity is most preferable.

If for example the microwave supplying means 108 comprises a slotted endless circular waveguide, there are a cooling water flowpassage and a slotted antenna. The slotted antenna serves to produce a surface standing wave due to interference, at the vacuum side of the dielectric material window 107 surface. The slotted antenna comprises a metallic disk plate having a radial slot, a circumferential slot, a large number of approximately T-shaped slots disposed concentrically or spirally, or four pairs of V-shaped slots, for example. Here, in order to assure uniform processing, without dispersion, entirely along the whole surface of the substrate 102 to be processed, it is important that active species having good uniformness along the substrate 102 surface are supplied. With the provision of one or more slots, the slotted antenna enables generation of plasma over a wide area and yet the controllability of the plasma strength and uniformness is facilitated.

Next, the oxide film (insulating film) forming operation of the processing apparatus 100 will be explained. First of all, a substrate 102 to be processed, having it surface cleaned in accordance with a known RCA process and a rare hydrofluoric acid washing method, is placed on the support table 103. Thereafter, the pressure adjusting mechanism 106 vacuum evacuates the plasma processing chamber 101. Subsequently, the valve (not shown) of the gas supplying means is opened, and a processing gas is supplied into the plasma processing chamber 101 from the gas introducing portion 105 and through the mass-flow controller, at a predetermined flow rate. Then, the pressure adjusting valve 106a is adjusted to keep a predetermined pressure inside the plasma processing chamber 101. Also, microwaves from the microwave generating source are supplied into the plasma processing chamber 101 through the microwave supplying means and the dielectric material window 107, such that plasma is generated inside the plasma processing chamber 101.

The microwaves introduced into the microwave supplying means 108 are propagated with a guide wavelength (wavelength in waveguide) longer than the free space wavelength, and from the slot and through the dielectric material window 107, it is introduced into the plasma processing chamber 101. Then, it is propagated along the surface of the dielectric material window 107 as a surface wave. This surface wave causes interference between adjacent slots, whereby a surface standing wave is produced. Due to the electric field of this surface standing wave, high density plasma is generated. Since the electron density in the plasma generating region is high, the processing gas can be dissociated efficiently. Furthermore, since the electric field is locally present near the dielectric material and because the electron temperature decreases fast as coming away from the plasma generating region, it is possible to suppress unwanted damage of the device. Active species in the plasma are conveyed to and around the substrate 102 by diffusion of the like, and then they reach the surface of the substrate 102.

In this embodiment, inside the plasma, not only active species such as oxygen ions or neutral oxygen radicals but also OH radicals which are active oxygen having highest oxidizing power can be produced easily. Even at a low temperature of 600° C. or less, the surface of the substrate 102 can be oxidized at high speed. Furthermore, the hydrogen atoms dissociated by the plasma and impinging on the substrate 102 surface are diffused easily within the oxide film, and they terminate the dangling bond of silicon. Defectives within the film caused by being exposed to ion bombardment during the plasma processing can be reduced, and consequently a high-quality insulating film having lower surface level or fixed charge is obtainable.

The silicon oxide film produced in the manner described above may be suitably used as a gate insulating film for MISFET (Metal Insulator Semiconductor Field Effect Transistor) or a gate insulating film for a flash memory, for example.

Next, specific applied examples of microwave plasma processing apparatus 100 will be described. It should be noted however that the present invention is not limited to these examples.

### EXAMPLE 1

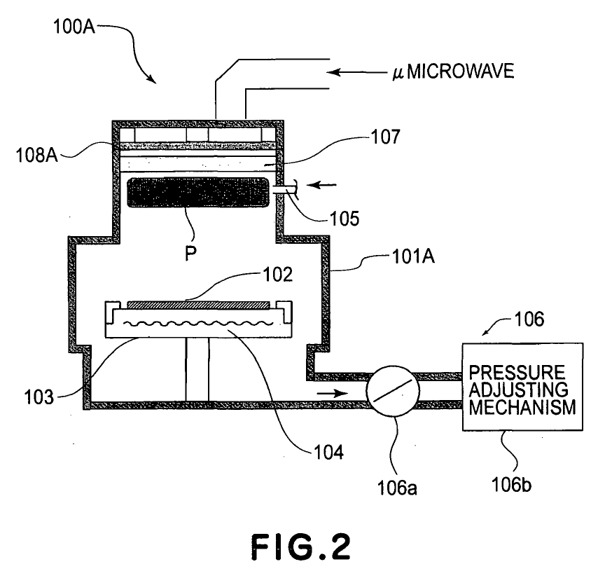

As an example of processing apparatus 100, a microwave plasma processing apparatus 100A shown in FIG. 2 was used to produce a gate insulating film for a semiconductor device. The processing apparatus 100A is arranged to cause excitement of surface wave interference plasma by microwaves. Denoted at 108A is a slotted endless circular waveguide (microwave supplying means) for introducing microwaves into a plasma processing chamber 101A through a dielectric material window 107. In FIG. 2, elements corresponding to those of FIG. 1 are denoted by corresponding reference numerals, while modified or specified elements are denoted by like numerals with an alphabetical suffix.

The slotted endless circular waveguide 108A had a TE10 mode and a sectional dimension of its inner wall of 27 mm×96 mm (guide wavelength 158.8 mm), and the center diameter of the waveguide was 151.6 mm (unit circumference is three times the guide wavelength). As regards the material of the waveguide 108A, it was made all of an aluminum alloy so as to suppress the propagation loss of microwaves. At the H-shaped surface of the circular waveguide 108A, there are slots formed to introduce microwaves into the plasma processing chamber 101A. Each slot has a rectangular shape having a length 40 mm and a width 4 mm. There are six slots which are formed at the position corresponding to the central diameter of 151.6 mm, and these slots are disposed radially with 60-degree intervals. To this circular waveguide 108A, a 4E tuner, a directional coupler, an isolator and a microwave voltage source having a frequency of 2.45 GHz (not shown) are connected in this order.

As regards the substrate 102 to be processed, an 8-inch P-type monocrystal silicon wafer (with a surface azimuth 100 and a specific resistance 10 Ωcm) was used. First of all, the substrate 102 was conveyed into the plasma processing chamber 101, and it was placed on the support table 103. At that time, the substrate 102 was heated to and kept at 400° C. by means of a heater 104.

Subsequently, the processing chamber 101A was vacuum evacuated sufficiently by using a vacuum pump, to a vacuum level of 10⁻³ Pa. After that, an O₂ gas and an NH₃ gas were introduced into the processing chamber, respectively, both at a flow rate of 500 sccm. The degree of opening of the pressure adjusting valve 106a was adjusted, and the inside pressure of the processing chamber 101A was held at 400 Pa. After that, a microwave electric voltage of 2.45 GHz and 1.5 kW was applied into the processing chamber 101A through the microwave supplying means 108A and the dielectric material window 107, whereby plasma P was produced. The silicon substrate was exposed to the thus produced oxygen plasma for 15 minutes, whereby it was reformed into a silicon oxide film.

The film thickness of the silicon oxide film formed in the manner described above was measured by using an ellipsometer, and it was 13.7 nm. The uniformness along the surface was 1.4%, and a good result was obtained.

Furthermore, by using a silicon oxide film produced in accordance with the processing method described above, a capacitor having an MOS structure was made, and C-V and I-V characteristics of the insulating film were evaluated. From the results, it was confirmed that there was approximately no flat band shift occurred.

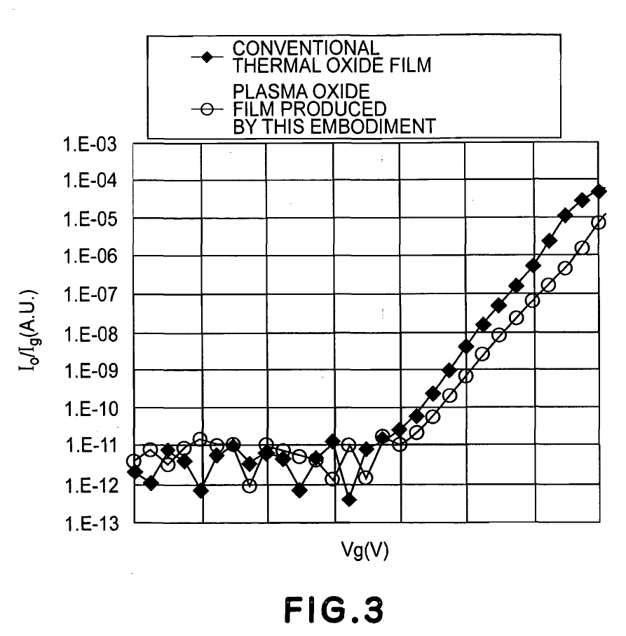

Furthermore, as shown in FIG. 3, the leak current was smaller by one digit than that of a thermal oxidation film, and it was confirmed that the oxide film had a good quality in that it was precise enough and the defectiveness was very small.

### EXAMPLE 2

The microwave plasma processing apparatus 100A shown in FIG. 2 was used to produce a gate insulating film for a semiconductor device.

As regards the substrate 102 to be processed, an 8-inch P-type monocrystal silicon wafer (with a surface azimuth 100 and a specific resistance 10 Ωcm), having a polycrystal silicon film formed on its surface by a PECVC method, was used. First of all, the substrate 102 was conveyed into the plasma processing chamber 101, and it was placed on the support table 103. At that time, the substrate 102 was heated to and kept at 400° C. by means of the heater 104.

Subsequently, the processing chamber 101A was vacuum evacuated sufficiently by using a vacuum pump, to a vacuum level of 10⁻³ Pa. After that, an O₂ gas, an NH₃ gas and a He gas were introduced into the processing chamber, respectively, at flow rates of 200 sccm, 200 sccm and 600 sccm, respectively. The degree of opening of the pressure adjusting valve 106a was adjusted, and the inside pressure of the processing chamber 101A was held at 400 Pa. After that, a microwave electric voltage of 2.45 GHz and 1.5 kW was applied into the processing chamber 101A through the microwave supplying means 108A and the dielectric material window 107, whereby plasma P was produced. The silicon substrate was exposed to the thus produced oxygen plasma for 12 minutes, whereby the polycrystal silicon already formed on the substrate 102 surface was reformed into a silicon oxide film.

The film thickness of the silicon oxide film formed in the manner described above was measured by using an ellipsometer, and it was 10.2 nm. The uniformness along the surface was 1.9%, and a good result was obtained.

Furthermore, by using a silicon oxide film produced in accordance with the processing method described above, a capacitor having an MOS structure was made, and electrical characteristics were evaluated. From the results, it was confirmed that there was approximately no flat band shift occurred and the quality of the oxide film was very good in that there were very small charges in the film.

### EXAMPLE 3

The microwave plasma processing apparatus 100A shown in FIG. 2 was used to perform corner rounding oxidation for STI (Shallow Trench Isolation).

As regards the substrate 102 to be processed, an 8-inch P-type monocrystal silicon wafer (with a surface azimuth 100 and a specific resistance 10 Ωcm), which was hard masked by Si₃N₄ and then etched to form an STI thereon, was used. First of all, the substrate 102 was conveyed into the plasma processing chamber 101, and it was placed on the support table 103. At that time, the substrate 102 was heated to and kept at 400° C. by means of the heater 104.

Subsequently, the processing chamber 101A was vacuum evacuated sufficiently by using a vacuum pump, to a vacuum level of 10⁻³ Pa. After that, an O₂ gas, an NH₃ gas and an Ar gas were introduced into the processing chamber, respectively, at flow rates of 1000 sccm, 200 sccm and 800 sccm, respectively. The degree of opening of the pressure adjusting valve 106a was adjusted, and the inside pressure of the processing chamber 101A was held at 400 Pa. After that, a microwave electric voltage of 2.45 GHz and 1.5 kW was applied into the processing chamber 101A through the microwave supplying means 108A and the dielectric material window 107, whereby plasma P was produced. The silicon substrate was exposed to the thus produced oxygen plasma for 10 minutes, whereby the substrate silicon portion being exposed (uncovered) at the STI pattern surface was oxidized. Sectional observation by using TEM was carried out to the STI sample having been rounded as described above, this observation being also made to a sample having been rounding-oxidized by thermal oxidization, for comparison. From the results, it was confirmed that, at both of the top corner and bottom corner of the STI, satisfactory shapes like those of the thermally oxidized sample were obtained.

### EXAMPLE 4

The microwave plasma processing apparatus 100A shown in FIG. 2 was used to perform condensed oxidation of SiGe, which is usable for strained silicon.

As regards the substrate 102 to be processed, an 8-inch SOI (Silicon On Insulator) wafer was used. The substrate 102 had a SiGe epitaxy layer thereon, being doped with 5% Ge. First of all, the substrate 102 was conveyed into the plasma processing chamber 101, and it was placed on the support table 103. At that time, the substrate 102 was heated to and kept at 400° C. by means of the heater 104.

Subsequently, the processing chamber 101A was vacuum evacuated sufficiently by using a vacuum pump, to a vacuum level of 10⁻³ Pa. After that, an O₂ gas and an NH₃ gas were introduced into the processing chamber, respectively, at a flow rate of 500 sccm. The degree of opening of the pressure adjusting valve 106a was adjusted, and the inside pressure of the processing chamber 101A was held at 400 Pa. After that, a microwave electric voltage of 2.45 GHz and 1.5 kW was applied into the processing chamber 101A through the microwave supplying means 108A and the dielectric material window 107, whereby plasma P was produced. The silicon substrate was exposed to the thus produced oxygen plasma for 20 minutes, whereby the surface portion of the SiGe was oxidized. The SOI wafer oxidized in the manner described above was analyzed by using RBS and, from the results, it was confirmed that a SiGe layer having a high density Ge of 20% or more was formed below a silicon dioxide layer produced by the plasma oxidation.

Although the present invention has been described with reference to preferred embodiments and examples, the present invention is not limited to them. Various changes and modifications are possible within the scope of the present invention.

While the invention has been described with reference to the structures disclosed herein, it is not confined to the details set forth and this application is intended to cover such modifications or changes as may come within the purposes of the improvements or the scope of the following claims.

This application claims priority from Japanese Patent Application No. 2004-323693 filed Nov. 8, 2004, for which is hereby incorporated by reference.

What is claimed is:

1. An insulating film forming method in which a material to be processed, which is exposed at a surface of a substrate to be processed, is oxidized in accordance with a plasma oxidation method and by use of at least a gas that contains hydrogen atoms other than H₂ and H₂O and a gas that contains oxygen atoms other than H₂O, to produce an insulating film for a semiconductor device.

2. A method according to claim 1, wherein the gas that contains hydrogen atoms other than H₂ and H₂O comprises one of NH₃, CH₄, HCl, HBr and HI, and wherein the gas that contains oxygen atoms other than H₂O comprises at least one of O₂, O₃, NO, N₂O, NO₂, CO and CO₂.

3. A method according to claim 1, wherein the plasma oxidation process is carried out while the substrate to be processed is placed on a support table, and wherein the support table is maintained at a temperature not greater than 600° C.

4. A method according to claim 3, wherein the temperature of the support table is maintained in a range from 200° C. to 400° C.

5. A method according to claim 1, wherein the material exposed at the surface of the substrate to be processed comprises at least one of monocrystal silicon, polycrystal silicon, amorphous silicon, silicon carbide and silicon germanium.

6. A method according to claim 1, wherein the plasma oxidation process uses a plasma source which is based on surface wave plasma.

7. An insulating film forming apparatus in which a material to be processed, which is exposed at a surface of a substrate to be processed, is oxidized by use of plasma oxidizing means to produce an insulating film for a semiconductor device, characterized by means for performing plasma processing by use of at least a gas that contains hydrogen atoms other than H₂ and H₂O and a gas that contains oxygen atoms other than H₂O.
